(19) United States
(12) Patent Application Publication
(10) Pub. No.: US 2018/0233623 A1
(43) Pub. Date: Aug. 16, 2018

(54) ANTI-BLOCKING SYSTEM

(71) Applicant: GUANGDONG HANERGY THIN-FILM SOLAR CO., LTD., Heyuan (CN)

(72) Inventors: Jinghong SU, Heyuan (CN); Liqiang BAO, Heyuan (CN); Huizhou ZHANG, Heyuan (CN); Wenbo LAI, Heyuan (CN); Jie ZHENG, Heyuan (CN); Zhigang NIAN, Heyuan (CN); Jian ZHOU, Heyuan, (CN)

(21) Appl. No.: 15/950,636

(22) Filed: Apr. 11, 2018

Related U.S. Application Data
(63) Continuation of application No. PCT/CN2016/101580, filed on Oct. 9, 2016.

(30) Foreign Application Priority Data
Oct. 12, 2015 (CN) 201520789277.7

(51) Int. Cl. H01L 31/18; H01L 21/66; G01V 3/10; B65G 43/08

(52) U.S. Cl. CPC H01L 31/1876; H01L 22/20; B65G 2811/093; B65G 43/08; G01V 3/10

(57) ABSTRACT

An anti-blocking system includes a first device, a second device and a first transmission line. The first transmission line is configured to transfer a plurality of objects from the first device to the second device. The first device includes a side surface close to a second device. The second device includes a first swing sensor and a second swing sensor configured to detect whether or not a blockage occurs in the plurality of objects, wherein the first swing sensor is disposed at a side of the side surface away from the second device and the second swing sensor is disposed inside the second device.

### CROSS-REFERENCE TO RELATED APPLICATION

This application is a bypass continuation Application of PCT/CN2016/101580 filed on Oct. 9, 2016, which claims priority to Chinese Patent Application No. 201520789277.7 filed on Oct. 12, 2015, titled “ANTI-BLOCKING CHIP SYSTEM OF COMBINATION OF AN EDGING MACHINE AND A SINGLE CLEANING MACHINE FOR SOLAR CELL”, the entirety of which is incorporated herein by reference.

### TECHNICAL FIELD

The present disclosure relates to a field of solar cell technology, and in particular to an anti-blocking system.

### BACKGROUND

In the field of solar cell production, chip's edging and cleaning are front and back processes, respectively. A cleaning machine and an edging machine each has its own photoelectric sensor, and each has its own software alarm system. If a blocking alarm occurs in the cleaning machine, the cleaning machine sends a warning signal to make the edging machine and a transmission line stop transmitting chips, to prevent a batch of chips from flowing down resulting in these chips being blocked and scrapped. However, due to the fact that the current single cleaning machine uses photoelectric sensors and the photoelectric sensors have poor waterproof capabilities, miscalculations often occur in actual production. After the single cleaning machine sends the warning signal, the edging machine and the transmission line do not stop transmitting the chips, and multiple batch chips are blocked and scrapped accordingly.

### SUMMARY

Some embodiments of the present disclosure provide an anti-blocking system. The system comprises a first device, a second device and a first transmission line, the first transmission line being configured to transfer a plurality of objects from the first device to the second device, wherein

the first device comprises a side surface close to the second device;

the second device comprises a first swing sensor and a second swing sensor configured to detect whether or not a blockage occurs in the plurality of objects, the first swing sensor is disposed at a side of the side surface away from the second device and the second swing sensor is disposed inside the second device.

Some embodiments of the present disclosure provide an anti-block chip system of combination of an edging machine and a single cleaning machine for solar cell. This system comprises an edging machine and a single cleaning machine, wherein a discharge outlet of the edging machine and a feed inlet of the single cleaning machine are connected through a transmission line; the edging machine and the single cleaning machine each is internally provided with at least one swing sensor, and each of the at least one swing sensor comprises a swing base unit and a base unit; the swing base unit comprises a swing head and a swing base, and an upper portion of the swing head is connected with the swing base through a stainless steel shaft; a roller is provided at an upper end of the swing head; a center of the roller is coupled with the swing head through a plastic shaft; a cylindrical magnet is provided on a lower portion of the swing head; the base unit comprises a connecting shaft and a base; a lower portion of the connecting shaft is connected with the base through a sealing ring; a upper portion of the connecting shaft is connected with the swing base through another sealing ring; a through hole is provided in the connecting shaft along an axis of the connecting shaft, a gasket is placed on top of the connecting shaft, a magnetic switch is provided on top of the gasket, and a wire at a rear end of the magnetic switch passes through a center of the gasket and the axis of the connecting shaft.

### BRIEF DESCRIPTION OF THE DRAWINGS

FIG. 1 is a schematic structure diagram of an anti-blocking chip system according to some embodiments of the present disclosure;

FIG. 2 is a schematic structure diagram of another anti-blocking chip system according to some embodiments of the present disclosure;

FIG. 3 is a schematic structure diagram of still another anti-blocking chip system according to some embodiments of the present disclosure;

FIG. 4 is a schematic structure diagram of a swing sensor according to some embodiments of the present disclosure;

FIG. 5 is a schematic structure diagram of a swing base unit according to some embodiments of the present disclosure;

FIG. 6 is a schematic structure diagram of a base unit according to some embodiments of the present disclosure;

FIG. 7 is a schematic structure diagram of an anti-blocking system according to some embodiments of the present disclosure;

FIG. 8 is a schematic structure diagram of another anti-blocking system according to some embodiments of the present disclosure; and

FIG. 9 is a schematic structure diagram of still another anti-blocking system according to some embodiments of the present disclosure.

### DETAILED DESCRIPTION

In order to enable those skilled in the art to better understand the technical solutions of the present disclosure, the products of the present disclosure will be further described in detail below in conjunction with the embodiments and the accompanying drawings.

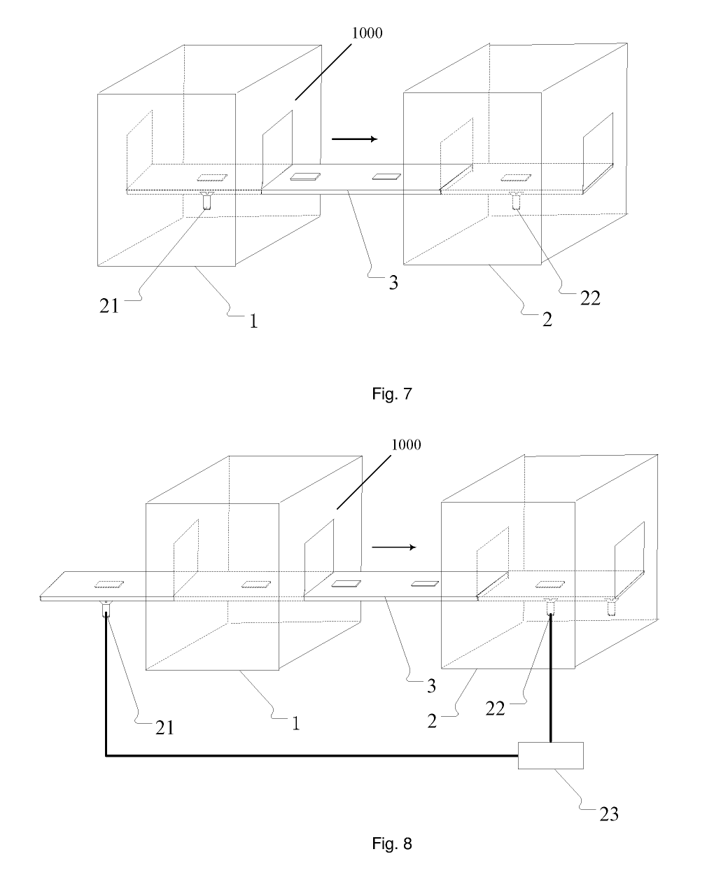

Some embodiments of the present disclosure provide an anti-blocking system. As shown in FIG. 7, the system includes a first device 1, a second device 2 and a first transmission line 3, and the first transmission line 3 is configured to transfer a plurality of objects from the first device 1 to the second device 2. The first device 1 includes a side surface 1000 close to the second device 2, and the second device 2 includes a first swing sensor 21 and a second swing sensor 22 configured to detect whether or not a blockage occurs in the plurality of objects. The first swing sensor 21 is disposed at a side of the side surface 1000 away from the second device 2. The second swing sensor 22 is disposed inside the second device 2.

By disposing a swing sensor instead of a conventional photoelectric sensor at the side of the side surface 1000 away from the second device 2, in cases where the second device 2 cleans the objects with water, a problem of inaccurate sensing caused by a non-waterproof photoelectric sensor may be avoided. Therefore, a hidden trouble caused by a continuous feeding of the first device 1 may be avoided when the objects are jammed, so that the stability of the operation of the system may be ensured.

Furthermore, compared with the photoelectric sensors being arranged inside the second device 2, by arranging the first swing sensor 21 of the second device 2 at the side of the side surface 1000 of the first device 1 away from the second device 2, and setting the second swing sensor 22 inside the second device 2, it is possible to detect the blocking of the objects on the first transmission line between the first device 1 and the second device 2, thereby expanding the detection range.

It will be noted that both the first device and the second device are any processing devices, and the object is any transportable object. For example, the first device 1 is an edging machine for solar cell and is configured to edge a chip. The second device 2 is a cleaning machine configured to clean the chip. Here, the object is a chip. The first transmission line 3 is any transmission line for transmitting objects, which is set according to the objects being transported. The first transmission line 3 is, for example, a rolling transmission line. It will be noted that, the edging machine for solar cell includes a discharge outlet adjacent to the cleaning machine, and the first swing sensor 21 is disposed at a side of a side surface of the edging machine for solar cell away from the cleaning machine, so that the operation of the first swing sensor is not affected when the chip is being cleaned at the discharge outlet. In some embodiments, the object is a glass substrate, a chip, a sheet metal part, or the like.

In some embodiments of the present disclosure, as shown in FIG. 8, the second device 2 further includes a controller 23 configured to detect a first time point of an object passing through the first swing sensor 21 among the plurality of objects, and to determine whether the object reaches the second swing sensor 22 within a predetermined period of time from the first time point. In some examples, in cases where the object reaches the first swing sensor 21, the first swing sensor 21 sends a signal to the controller 23, and the controller 23 receives the signal and marks the receiving time as a first time point. Then, the controller 23 determines whether a signal transmitted by the second swing sensor 22 is received within a predetermined period of time from the first time point. If the signal transmitted by the second swing sensor 22 is received within the predetermined period of time, it indicates that a jam of objects does not occur between the first swing sensor 21 and the second swing sensor 22. If the signal transmitted by the second swing sensor 22 is not received within the predetermined period of time, it indicates that the jam of objects occurs between the first swing sensor 21 and the second swing sensor 22. The predetermined period of time is, for example, 80 s, 150 s, etc., and a person skilled in the art can set the period of time according to the positions of the first and second swing sensors 21 and 22 and the preset transmission speed of the object.

In some embodiments, the controller 23 is further configured to send an alarm and stop the first device 1 and the second device 2 when the object does not reach the second swing sensor 22 within the predetermined period of time. For example, the controller 23 sends a signal to a controller of the first device 1 so that the controller of the first device 1 stops the first device. With this arrangement, when a jam of objects occurs between the first swing sensor 21 and the second swing sensor 22, the transmission of objects may be stopped. For the description of the controller of the first device 1, see the description of the controller 23, which will not be described herein.

In some embodiments, the controller 23 is implemented by a microprocessor programmed to perform one or more of the operations and/or functions described in the present disclosure. In some embodiments, the controller 23 is implemented in whole or in part by specially configured hard ware (e.g., by one or more application-specific integrated circuits or ASICs). The number of controllers 23 is not particularly limited and can be set according to the number of the second swing sensor 22.

In some embodiments, as shown in FIG. 7, the first swing sensor 21 is disposed inside the first device 1. In some examples, the first swing sensor 21 is disposed at an intermediate position of the transmission line inside the first device 1 perpendicular to the transmitting direction so that the object is able to pass over the first swing sensor 21. In some examples, the first swing sensor 21 is disposed at a center position of the first device 1 in the transmitting direction. Please refer to the first transmission line 3 for this transmission line, which will not be repeated here.

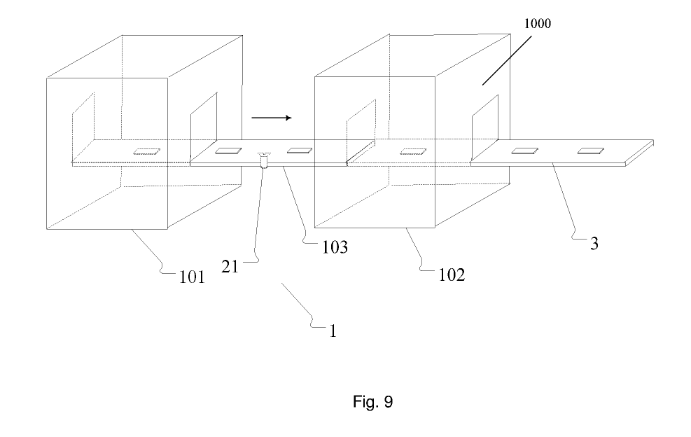

In some examples, as shown in FIG. 9, the first device 1 includes a first sub-device 101, a second sub-device 102, and a turntable 103. The turntable 103 is disposed between the first sub-device 101 and the second sub-device 102, and configured to transmit the plurality of objects from the first sub-device 101 to the second sub-device 102. The first swing sensor 21 is disposed on the turntable 103. In some embodiments, the turntable 103 has the same structure as the first transmission line. In other embodiments, the turntable 103 is further configured to rotate an object thereon. For example, the first device is an edging machine, which includes an edging machine A and an edging machine B. A turntable is disposed between the edging machine A and the edging machine B. The turntable is configured to transmit the objects from the edging machine A to the edging machine B, and the first swing sensor is disposed on the turntable. When the chip passes over the first swing sensor, the first swing sensor sends a signal to the controller 23 so that the controller 23 records the time point.

In the related art, the photoelectric sensor of the edging machine is arranged only on a feed inlet of the edging machine A and the turntable, because the chip needs to be cleaned with water in the edging machine B and thus the photoelectric sensor cannot be installed in the edging machine B. In addition, the photoelectric sensor of the cleaning machine (corresponding to the second device 2) is disposed at the feed inlet and the inside of the cleaning machine. In this case, the blocked chips between the turntable and the cleaning machine cannot be detected. In some embodiments of the present disclosure, the first swing sensor of the cleaning machine is disposed on the turntable of the edging machine, so that the blocked chips between the turntable and the cleaning machine may be detected, and the detection range may be expanded.

In other embodiments, as shown in FIG. 8, the first swing sensor 21 is disposed at a side of the first device 1 away from the second device 2. With this arrangement, the first swing sensor 21 is also not affected by the first device 1, and the detection range may be expanded.

The number and position of the second swing sensor 21 provided in the second device 2 is not limited in the present disclosure and those skilled in the art may set them according to actual needs. For example, the second device 2 includes a plurality of second swing sensors 22, one of which is disposed at the discharge outlet of the second device 2. In some embodiments, the second device 2 includes a plurality of first swing sensors 21. The positions of these first swing sensors 21 are described above, the number of these first swing sensors 21 is not specifically limited in the present disclosure, and those skilled in the art may set them as needed.

In some embodiments, the first device 1 includes at least one swing sensor and a controller. The at least one swing sensor is distributed on the transmission line within the first device and the controller is configured to determine if objects on the transmission line have been jammed. Please refer to the above controller for the structure of this controller, which will not be repeated here.

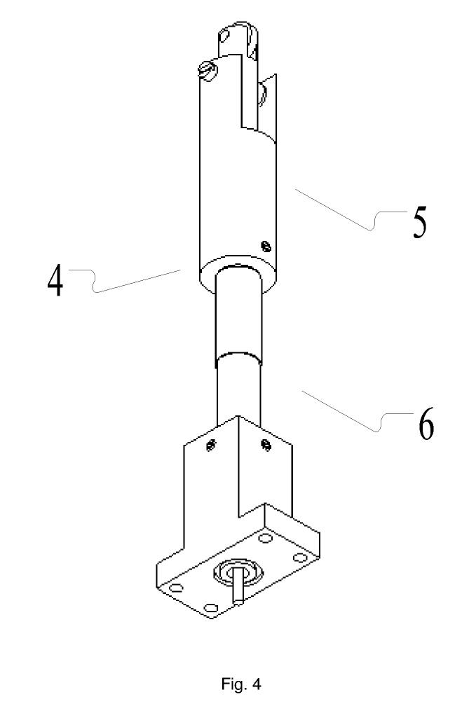

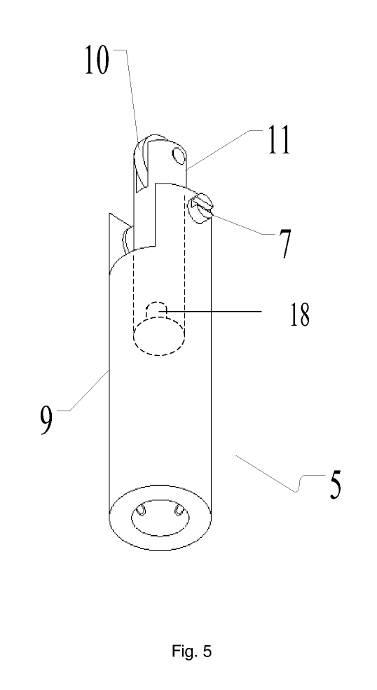

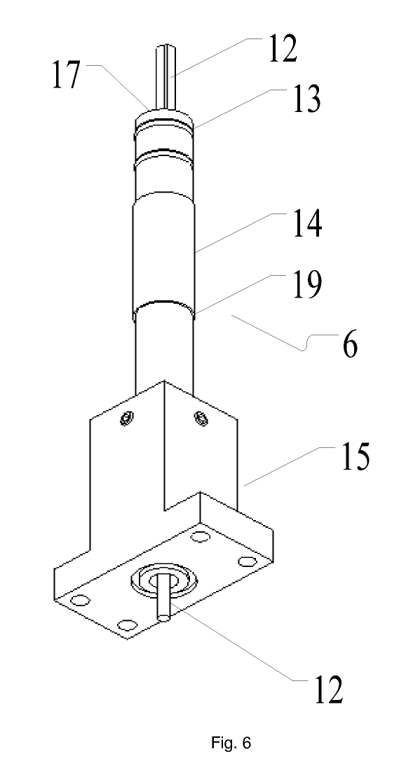

In some embodiments, as shown in FIGS. 4-6, each of the first swing sensor 21 and the second swing sensor 22 includes a swing base unit 5 and a base unit 6. The swing base unit 5 includes a swing head 11, a roller 10 disposed at one end of the swing head 11, a swing base 9 coupled to the swing head 11 through a shaft 7, and a magnet 18 disposed at an opposite end of the swing head 11. For example, the swing base 9 is coupled to a portion of the swing head 11 adjacent to the roller 10. For example, the magnet 18 is provided inside the swing head 11 at the opposite end thereof.

The base unit 6 includes a connecting shaft 14, and a base 15 coupled with one end of the connecting shaft 14. An opposite end of the connecting shaft 14 is coupled with the opposite end of the swing base 9. A through hole is provided in the connecting shaft 14 along the axis thereof. The base unit 6 further includes a magnetic switch 12 provided between the swing base 9 and the connecting shaft 14, and the magnetic switch 12 includes a wire arranged at the rear end thereof and passing through the axis of the connecting shaft 14.

In some embodiments, the center of the roller 10 is coupled with the swing head 11 through a plastic shaft.

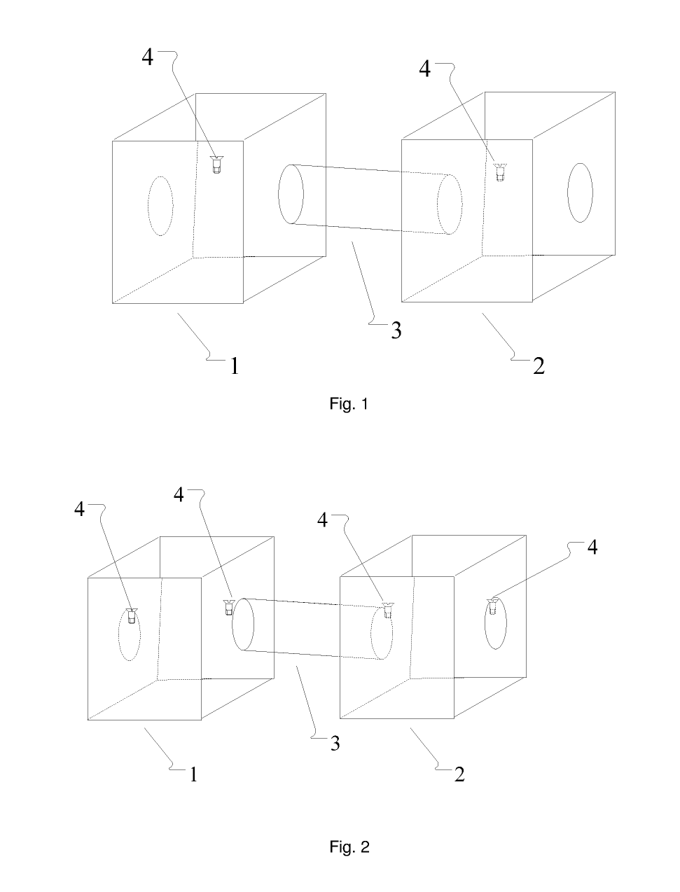

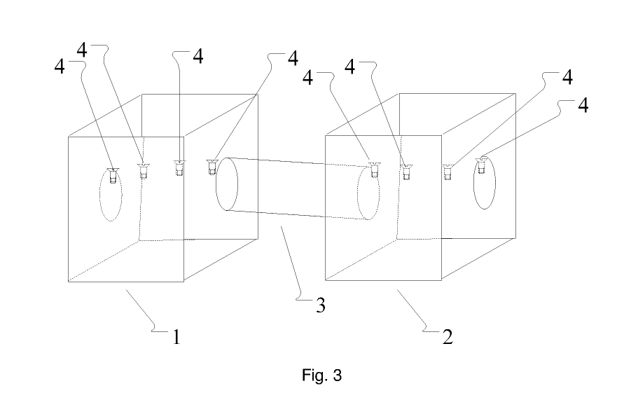

Some embodiments of the present disclosure provide an anti-blocking chip system of combination of an edging machine and a single cleaning machine for solar cell. As shown in FIGS. 1 to 6, the system includes an edging machine 1 and a single cleaning machine 2. A discharge outlet of the edging machine 1 and a feed inlet of the single cleaning machine 2 are connected through a transmission line 3. The edging machine 1 and the single cleaning machine 2 each is internally provided with at least one swing sensor 4. Each of the least one swing sensor 4 includes a swing base unit 5 and a base unit 6. The swing base unit 5 includes a swing head 11 and a swing base 9. An upper portion of the swing head 11 is coupled to the swing base 9 through a stainless steel shaft 7. A roller 10 is provided at an upper end of the swing head 11. A center of the roller 10 is coupled with the swing head 11 through a plastic shaft. A lower portion of the swing head 11 is provided with a cylindrical magnet 18. The base unit 6 includes a connecting shaft 14 and a base 15. A lower portion of the connecting shaft 14 is connected with the base 15 through a sealing ring 19. An upper portion of the connecting shaft 14 is connected with the swing base 9 through a sealing ring 13. A through hole is provided in the connecting shaft 14 along its axis. A gasket 17 is disposed on top of the connecting shaft. A magnetic switch 12 is provided on top of the gasket 17. A wire at a rear end of the magnetic switch 12 passes through a center of the gasket and the axis of the connecting shaft 14. The positions of the swing sensors 4 are adjustable in interiors of the edging machine 1 and the single cleaning machine 2, respectively. The number of the swing sensors 4 is 2-8. FIG. 1 shows an embodiment in which the number of swing sensors is two. FIG. 2 shows an embodiment in which the number of swing sensors 4 is four. FIG. 3 shows an embodiment in which the number of swing sensors 4 is eight.

In some embodiments, in FIGS. 1 to 3, all of the swing sensors 4 are set on the same straight line to ensure the accuracy of the sensing.

In some embodiments, the anti-blocking chip system of combination of an edging machine and a single cleaning machine for solar cell includes an edging machine and a single cleaning machine. The discharge outlet of the edging machine and the feed inlet of the single cleaning machine are connected by a transmission line. The interiors of the edging machine and the single cleaning machine are both provided with at least one swing sensor. The swing sensor includes a swing base unit and a base unit. The swing base unit includes a swing head and a swing base. A middle-upper portion of the swing head is connected with the swing base through a stainless steel shaft. An upper portion of the swing head is provided with a roller. A center of the roller is connected with the swing head through a plastic shaft. A cylindrical magnet is provided inside the lower portion of the swing head, and is cemented and sealed with glue. The cylindrical magnet is provided inside the lower portion of the swing head, and the quality of the cylindrical magnet is greater than that of the roller in the upper portion of the swing head. The stainless steel shaft passes through the middle-upper portion of the swing head. Due to the influence of gravity and under the condition of no external force, an end of the swing head having the roller on the upper portion thereof is on top, and an opposite end of the swing head having the cylindrical magnet inside the swing head is below. The base unit includes a connecting shaft and a base. The lower portion of the connecting shaft is connected with the base through two sealing rings. There are two hexagon socket screws fixed on the side surface of the base. The upper portion of the connecting shaft is connected with the swing base through two sealing rings. There are two hexagon socket screws fixed on the side surface of the swing base. A through hole is provided in the connecting shaft along the axis thereof. A gasket is disposed on top of the connecting shaft. A magnetic switch is provided on top of the gasket. A wire at a rear end of the magnetic switch just passes through a center of the gasket and the axis of the connecting shaft. An outer diameter of a head of the magnetic switch is larger, so the head cannot pass through the center of the gasket and the axis of the connecting shaft. The head of the magnetic switch can be just embedded in the inside of the swing base.

By using a swing sensor instead of a conventional photoelectric sensor provided inside the edging machine and the single cleaning machine, the problem of inaccurate sensing caused by the non-waterproof photoelectric sensor may be effectively overcome, and a hidden trouble caused by a continuous feeding of the edging machine and the transmission line under the failure of a single cleaning machine may be avoided, ensuring the stability of the system operation. By using the swing sensor in which the swing base unit and the base unit are in structural cooperation, the entire swing sensor may perform swing induction around the roller. The structure of the entire swing sensor is very simple, and assembly and maintenance are very convenient. The manufacturing cost of the swing sensor is effectively reduced, and thus the swing sensor has broad application prospects.

The positions of the swing sensors are adjustable in interiors of the edging machine and the single cleaning machine. During use, if the position of the swing sensor in the edging machine is adjusted forward and the position of the swing sensor in the cleaning machine is adjusted backward, the spacing between the two swing sensors is increased, and the alarm protection range is also increased. The alarm time may be set according to the time interval when the solar cell chip passes through two swing sensor.

The cylindrical magnet is disposed inside the lower portion of the swing head. The mass of the cylindrical magnet is greater than that of the roller on the upper portion of the swing head, and the stainless steel shaft passes through the middle-upper portion of the swing head. Due to the influence of gravity and under the condition of no external force, the end of the swing head having the roller on the upper portion thereof is on top, and the end of the swing head having the cylindrical magnet inside the swing head is below. This structure has a strong sensing reliability.

The upper portion of the swing head is provided with the roller. The center of the roller is coupled with the swing head through the plastic shaft. Here, the roller has micro-action and the friction force is extremely small. This structure has high sensing accuracy.

A cylindrical magnet is provided inside the lower portion of the swing head, and is cemented and sealed with glue. This structure has good waterproofness.

The lower portion of the connection shaft is connected with the base through two sealing rings, and two hexagon socket screws are fixed on the side surface of the base; the upper portion of the connection shaft is connected with the swing base through two sealing rings, and two hexagon socket screws are fixed on the side surface of the swing base. This structure has good waterproof.

The material of the gasket and the plastic shaft is a thermoplastic plastic, which has a low cost and certain softness, playing a certain buffering effect and having a long service life.

The anti-blocking chip system of combination of an edging machine and a single cleaning machine for solar cell provided by the embodiments of the present disclosure has the following beneficial effects.

Firstly, the sensing accuracy of the system is high. The roller is provided on the upper portion of a swing head. The roller's center is connected with the swing head through the plastic shaft. Here, the roller has a micro-action function and the friction force is extremely small. The structure has high sensing accuracy.

Secondly, the reliability of sensing of the system is strong. The cylindrical magnet is disposed inside a lower portion of the swing head. The mass of the cylindrical magnet is greater than that of the upper portion of the swing head, and the stainless steel shaft passes through the middle-upper portion of the swing head. Due to the influence of gravity and under the condition of no external force, the end of the swing head having the roller on the upper portion thereof is on top, and the end of the swing head having the cylindrical magnet inside the swing head is below. This structure has strong sensing reliability.

Thirdly, waterproofness of the system is good. The cylindrical magnet is provided inside the lower portion of the swing head, and is cemented and sealed with glue. This structure has good waterproofness; the lower portion of the connecting shaft is connected with the base through two sealing rings, and two hexagon socket screws are fixed on the side surface of the base; the upper portion of the connection shaft is connected with the swing base through two sealing rings, and two hexagon socket screws are fixed on the side surface of the swing base. This structure has good waterproofness.

Fourthly, the stability of the operation of the system is strong. By using a swing sensor instead of a conventional photoelectric sensor provided inside the edging machine and the single cleaning machine, the problem of inaccurate sensing caused by the non-waterproof photoelectric sensor is effectively overcome, and a hidden trouble caused by a continuous feeding of the edging machine and the transmission line under the failure of a single cleaning machine is avoided, ensuring the stability of the operation of the system.

Fifthly, the maintenance of the system is convenient. By using the swing sensor in which the swing base unit and the base unit are in structural cooperation, the entire swing sensor may perform swing induction around the roller. The structure of the entire swing sensor is very simple, and assembly and maintenance are very convenient.

Sixthly, the cost of the system is low. By using the swing sensor in which the swing base unit and the base unit are in structural cooperation, the entire swing sensor may perform swing induction around the roller. The structure of the entire swing sensor is very simple and the material cost is low, thereby effectively reducing the manufacturing cost of the swing sensor, and having broad application prospects.

The foregoing descriptions are merely some embodiments of the present disclosure and are not intended to limit the disclosure in any form. Those of ordinary skill in the art may smoothly implement the disclosure as shown in the accompanying drawings of the specification and the described above. However, those skilled in the art can make use of the above-disclosed technical contents to make some equivalent changes such as modifications, decorations and evolutions, without departing from the scope of the technical solution of the present disclosure, which are equivalent embodiments of the present disclosure. Meanwhile, any modification, decoration and evolution of any equivalent changes made from the above embodiments based on the essential technologies of the present disclosure are still within the protection scope of the technical solutions of the present disclosure.

What is claimed is:

1. An anti-blocking system, comprising a first device, a second device and a first transmission line, the first transmission line being configured to transfer a plurality of objects from the first device to the second device, wherein
the first device comprises a side surface close to the second device;
the second device comprises a first swing sensor and a second swing sensor configured to detect whether or not a blockage occurs in the plurality of objects, the first swing sensor is disposed at a side of the side surface away from the second device, and the second swing sensor is disposed inside the second device.

2. The anti-blocking system according to claim 1, wherein the second device further comprises a controller, and the controller is configured to:
detect a first time point of an object passing through the first swing sensor among the plurality of objects; and
determine whether the object reaches the second swing sensor within a predetermined period of time from the first time point.

3. The anti-blocking system according to claim 2, wherein the controller is further configured to send an alarm and stop the first device and the second device if the object does not reach the second swing sensor within the predetermined period of time.

4. The anti-blocking system according to claim 1, wherein the first swing sensor is disposed inside the first device.

5. The anti-blocking system according to claim 4, wherein the first device comprises a first sub-device, a second sub-device and a turntable disposed between the first sub-device and the second sub-device, and the first swing sensor is disposed on the turntable.

6. The anti-blocking system according to claim 1, wherein the first swing sensor is disposed at a side of the first device away from the second device.

7. The anti-blocking system according to claim 1, wherein the first device is an edging machine and the second device is a cleaning machine.

8. The anti-blocking system according to claim 1, wherein each of the first and second swing sensors comprises:
a swing base unit, wherein the swing base unit comprises a swing head, a roller disposed at one end of the swing head, a swing base coupled with the swing head through a shaft, and a magnet disposed at an opposite end of the swing head.

9. The anti-blocking system according to claim 1, wherein each of the first and second swing sensors comprises:
a base unit, wherein the base unit comprises a connecting shaft and a base coupled with one end of the connecting shaft, wherein an opposite end of the connecting shaft is coupled with the opposite end of the swing base, a through hole is provide in the connecting shaft along an axis of the connecting shaft, the base unit further comprises a magnetic switch provided between the swing base and the connecting shaft, and the magnetic switch comprises a wire arranged at a rear end of the magnetic switch and passing through the axis of the connecting shaft.

10. The anti-blocking chip system according to claim 8, wherein a center of the roller is coupled to the swing head by a plastic shaft.

11. An anti-block chip system in combination of an edging machine and a single cleaning machine for solar cell, comprising:
an edging machine; and
a single cleaning machine, wherein a discharge outlet of the edging machine and a feed inlet of the single cleaning machine are connected through a transmission line; the edging machine and the single cleaning machine each is internally provided with at least one swing sensors.

12. The anti-block chip system of claim 11, wherein each of the at least one swing sensors comprises a swing base unit and a base unit, wherein the swing base unit comprises a swing head and a swing base, and an upper portion of the swing head is connected with the swing base through a stainless steel shaft; a roller is provided at an upper end of the swing head; a center of the roller is coupled with the swing head through a plastic shaft; a cylindrical magnet is provided on a lower portion of the swing head; the base unit comprises a connecting shaft and a base; a lower portion of the connecting shaft is connected with the base through a sealing ring; an upper portion of the connecting shaft is connected with the swing base through another sealing ring; a through hole is provided in the connecting shaft along an axis of the connecting shaft, a gasket is placed on top of the connecting shaft, a magnetic switch is provided on top of the gasket, and a wire at a rear end of the magnetic switch passes through a center of the gasket and the axis of the connecting shaft.

13. The anti-block chip system in combination of an edging machine and a single cleaning machine for solar cell according to claim 11, wherein positions of at least one swing sensors are adjustable in interiors of the edging machine and the single cleaning machine, respectively.
